(19) United States
(12) Patent Application Publication
(10) Pub. No.: US 2015/0160276 A1
(43) Pub. Date: Jun. 11, 2015

(54) SYSTEM FOR INSPECTING DISPLAY PANEL

(71) Applicant: SAMSUNG DISPLAY CO., LTD., Yongin-City (KR)

(72) Inventors: Jong-Won Moon, Yongin-City (KR); Dong-Hwan Lee, Yongin-City (KR)

(21) Appl. No.: 14/553,986

(22) Filed: Nov. 25, 2014

(30) Foreign Application Priority Data
Dec. 11, 2013 (KR) 10-2013-0153800

(51) Int. Cl. G01R 27/02; G09G 3/00

(52) U.S. Cl. CPC G01R 27/02; G09G 3/006

(57) ABSTRACT

A system for inspecting a display panel includes the display panel, a driving circuit unit and a controller. The display panel includes a plurality of pixels positioned in a display area, and first and second test pads positioned in a non-display area. The driving circuit unit is positioned in the non-display area of the display panel, and includes first and second test bumps respectively bonded to the first and second test pads. The controller calculates a bonding resistance between the first and second test pads and the first and second test bumps.

### CROSS-REFERENCE TO RELATED APPLICATION

This application claims priority to and the benefit of Korean Patent Application No. 10-2013-0153800, filed on Dec. 11, 2013, in the Korean Intellectual Property Office, the contents of which are incorporated herein by reference in their entirety.

### BACKGROUND

1. Field

Embodiments of the present invention relate to a system for inspecting a display panel.

2. Description of the Related Art

In general, a display panel may be divided into a display area and a non-display area. A plurality of pixels coupled to scan lines and data lines may be positioned in the display area, and a plurality of scan pads and a plurality of data pads, which are coupled to the scan lines and the data lines, may be positioned in the non-display area.

A driving circuit unit is a chip for driving the display panel, and may be positioned in the non-display area of the display panel.

The methods of mounting the driving circuit unit in the display panel includes a chip on glass (COG) method, a tape carrier package (TCP) method, a chip on film (COF) method, and the like. Among these methods, the COG method has a simple structure, as compared with the TCP method and/or the COF method. Hence, recently the COG method has been widely used.

In the COG method, the driving circuit unit is bonded to pads positioned in the non-display area. In the COG method, when a failure occurs in the bonding process, a high bonding resistance occurs between the pads and the driving circuit unit.

Therefore, a determination is made as to whether a failure has occurred in a product by measuring the bonding resistance before the product is released.

### SUMMARY

According to an embodiment of the present invention, there is provided a system for inspecting a display panel having a non-diplay area and a display area comprising a plurality of pixels, the system including: first and second test pads in the non-display area; a driving circuit in the non-display area, the driving circuit including first and second test bumps respectively bonded to the first and second test pads; and a controller to calculate a bonding resistance between the first and second test pads and the first and second test bumps.

The display panel may further include a coupling line configured to couple the first and second test pads to each other.

The driving circuit may further include a first register to store a reference value; a voltage supply unit to output a reference voltage corresponding to the reference value; a comparator to compare a first voltage input from the first test bump with the reference voltage; and a test power unit to supply a test voltage to the second test bump.

The driving circuit may further include a reference resistor coupled to the first test bump.

The comparator may be configured to output a first result signal when a difference between the first voltage and the reference voltage is within a specific error range, and to output a second result signal when the difference between the first voltage and the reference voltage is not within the specific error range.

The first register may be configured to change the reference value when the second result signal is output from the comparator.

The controller may be configured to change the reference value stored in the first register unit when the second result signal is output from the comparator.

The controller may be configured to calculate the bonding resistance, using the reference voltage, the reference resistance and the test voltage, when the first result signal is output from the comparator.

The controller may be configured to calculate the bonding resistance, using the following equation:

Vref={Rref/(Rb+Rref)}*Vtest,

wherein Vref is the reference voltage, Rref is the reference resistance, Rb is the bonding resistance, and Vtest is the test voltage.

The voltage supply unit may be configured to change the reference voltage when the second result signal is output from the comparator.

The system may further include a plurality of data pads in the non-display area, and a plurality of data lines coupled between the data pads and the pixels.

The system may further include a plurality of scan pads in the non-display area, and a plurality of scan lines coupled between the scan pads and the pixels.

The driving circuit may further include a plurality of data bumps coupled to the data pads, and a data driver to supply data signals to the data bumps.

The driving circuit may further include a plurality of scan bumps coupled to the scan pads, and a scan driver to supply scan signals to the scan bumps.

### BRIEF DESCRIPTION OF THE DRAWINGS

Example embodiments of the present invention will be described more fully hereinafter with reference to the accompanying drawings; however, the present invention may be embodied in different forms and should not be construed as limited to the embodiments set forth herein. Rather, these embodiments of the present invention are provided so that this disclosure will be thorough and complete, and will fully convey the scope of the example embodiments of the present invention to those skilled in the art.

In the drawing figures, dimensions may be exaggerated for clarity of illustration. It will be understood that when an element is referred to as being “between” two elements, it can be the only element between the two elements, or one or more intervening elements may also be present.

FIG. 1 is a diagram illustrating a system for inspecting a display panel according to an embodiment of the present invention.

FIG. 2 is a diagram illustrating a display panel according to an embodiment of the present invention.

FIG. 3 is a diagram illustrating a state in which a driving circuit unit is bonded to the display panel according to an embodiment of the present invention.

FIG. 4 is a diagram illustrating the driving circuit unit according to an embodiment of the present invention.

### DETAILED DESCRIPTION

Hereinafter, certain exemple embodiments according to the present invention will be described with reference to the accompanying drawings. Here, when a first element is described as being coupled to a second element, the first element may be directly coupled to the second element but may also be indirectly coupled to the second element via a third element. Further, some of the elements that are not essential to the complete understanding of the invention are omitted for clarity. Also, like reference numerals refer to like elements throughout.

Expressions such as “at least one of,” when preceding a list of elements, modify the entire list of elements and do not modify the individual elements of the list. Further, the use of “may” when describing embodiments of the present invention refers to “one or more embodiments of the present invention.”

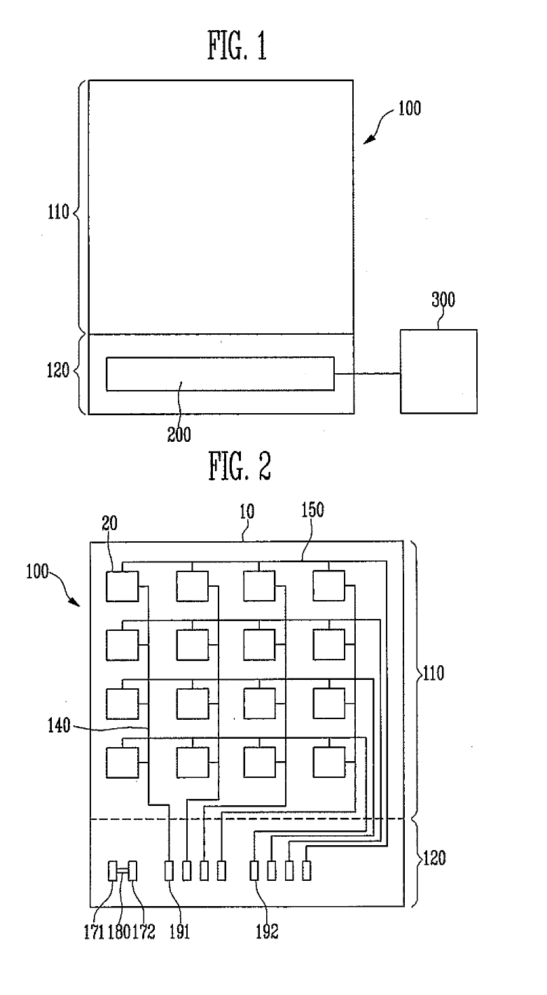

FIG. 1 is a diagram illustrating a system for inspecting a display panel according to an embodiment of the present invention.

Referring to FIG. 1, the system according to this embodiment may include a display panel 100 which includes a display area 110 and a non-display area 120. The system may further include a driving circuit unit 200 and a controller 300.

The driving circuit unit 200 may be attached to the display panel 100, so as to drive the display panel 100. For example, the driving circuit unit 200 may be positioned in a non-display area 120.

The driving circuit unit 200 may be implemented in the form of an integrated circuit (IC).

The controller 300 is used to measure a bonding resistance generated as the driving circuit unit 200 is attached to the display panel 100. The controller 300 may be coupled to the driving circuit 200 by being positioned at an outside of the display panel 100.

FIG. 2 is a diagram illustrating the display panel according to an embodiment of the present invention.

Referring to FIG. 2, the display panel 100 according to the present embodiment may include a plurality of pixels 20.

The pixels 20 may be positioned in a display area 110. The pixels 20 may perform an emission operation under the control of the driving circuit unit 200.

The non-display area 120, as shown in FIG. 2, may be positioned at one side of the display area 110.

The display panel 100 according to the present embodiment may include a plurality of data lines 140 and a plurality of data pads 191, configured to supply data signals to the pixels 20.

The data pads 191 may be positioned in the non-display area 120 of the display panel 100. The data pads 191 may receive data signals supplied from the driving circuit unit 200.

The data lines 140 may be coupled between the data pads 191 and the pixels 20. Thus, the data lines 140 may provide the pixels 20 with the data signals supplied to the data pads 191.

The display panel 100 according to the present embodiment may include a plurality of scan lines 150 and a plurality of scan pads 192, configured to supply scan signals to the pixels 20.

The scan pads 192 may be positioned in the non-display area 120 of the display panel 100. The scan pads 192 may receive scan signals supplied from the driving circuit unit 200.

The scan lines 150 may be coupled between the scan pads 192 and the pixels 20. The scan lines 150 may provide the pixels 20 with the scan signals supplied to the scan pads 192.

The numbers of the pixels 20, the data lines 140, the scan lines 150, the data pads 191 and the scan pads 192 may vary.

The pixels 20, the data lines 140, the scan lines 150, the data pads 191 and the scan pads 192 may be positioned on a substrate 10 constituting the display panel 100.

The display panel 100 may include a first test pad 171 and a second test pad 172. The first and second test pads 171 and 172 may be installed in the non-display area 120 separately from data pads 191 and scan pads 192, so as to allow measuring of a bonding resistance of the display panel 100 when bonded with the driving circuit unit 200.

The first and second test pad 171 and 172 may be electrically coupled to each other. The display panel 100 may further include a coupling line 180 configured to electrically couple the first and second test pads 171 and 172 to each other.

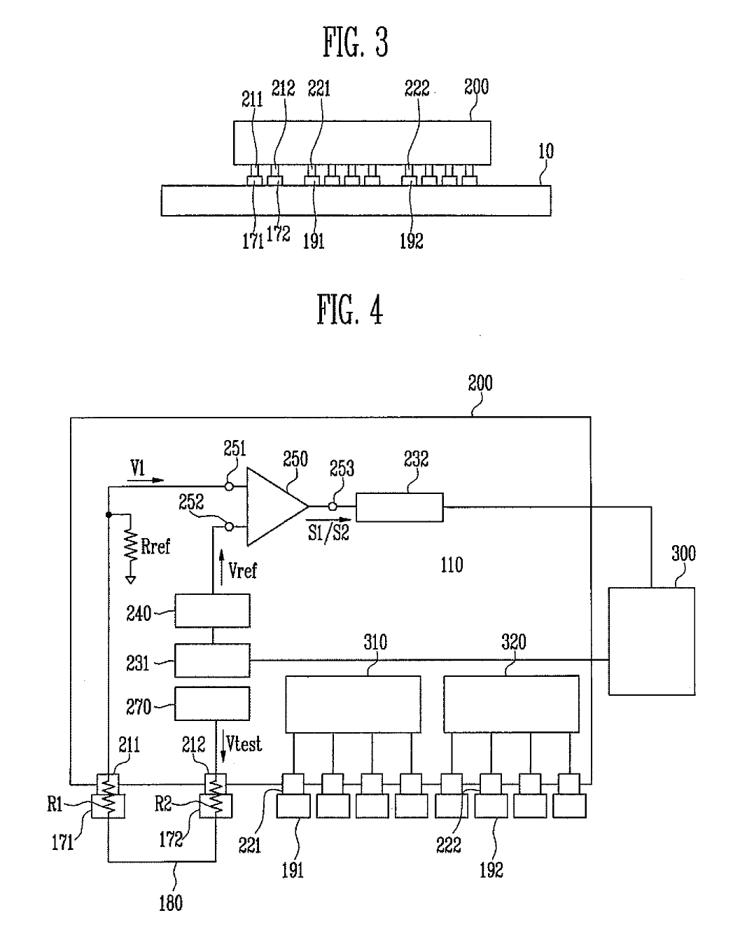

FIG. 3 is a diagram illustrating a state in which the driving circuit unit is bonded to the display panel according to an embodiment of the present invention.

Referring to FIG. 3, the driving circuit unit 200 according to the present embodiment may include a first test bump 211 and a second test bump 212.

The first and second test bumps 211 and 212 of the driving circuit unit 200 may be respectively bonded to the first and second test pads 171 and 172 positioned in the display panel 100.

For example, the first test bump 211 may be bonded to the first test pad 171, and the second test bump 212 may be bonded to the second test pad 172.

The bonding between the test bump 211 or 212 and the test pad 171 or 172 may be performed using a conductive adhesive. For example, an anisotropic conductive film (ACF) may be used to bond the test bump 211 or 212 and the test pad 171 or 172.

The controller 300 may calculate a bonding resistance generated by the bonding between the test bump 211 or 212 and the test pad 171 or 172.

The driving circuit unit 200 according to this embodiment may include a plurality of data bumps 221.

The data bumps 221 may be bonded to the data pads 191 positioned in the display panel 100.

Thus, the driving circuit unit 200 may supply data signals to the data lines 140 through the data bumps 221 and the data pads 191.

The bonding between the data bumps 221 and the data pads 191 may be performed using a conductive adhesive. For example, an ACF may be used to bond the data bumps 221 and the data pads 191.

The driving circuit unit 200 according to this embodiment may include a plurality of scan bumps 222.

The scan bumps 222 may be bonded to the scan pads 192 positioned in the display panel 100.

Thus, the driving circuit unit 200 may supply scan signals to the scan lines 150 through the scan bumps 222 and the scan pads 192.

The bonding between the scan bumps 222 and the scan pads 192 may be performed using a conductive adhesive. For example, an ACF may be used to bond the scan bumps 222 and the scan pads 192.

FIG. 4 is a diagram illustrating the driving circuit unit according to an embodiment of the present invention. In FIG. 4, the resistance generated by the bonding between the first test bump 211 and the first test pad 171 is represented as a first bonding resistance R1, and the resistance generated by the bonding between the second test bump 212 and the second test pad 172 is represented as a second bonding resistance R2.

Referring to FIG. 4, the driving circuit unit 200 according to the present embodiment may include a first register unit 231, a voltage supply unit 240, a comparator 250, a test power unit 270 and a reference resistor Rref.

The first register unit 231 may store a reference value. The first register unit 231 may change the stored reference value under the control of the controller 300, or change the stored reference value by reflecting a result signal output from the comparator 250.

The voltage supply unit 240 may output a reference voltage Vref corresponding to the reference value stored in the first register unit 231.

Thus, when the reference value stored in the first register unit 231 is changed, the reference voltage Vref output from the voltage supply unit 240 may also be changed.

The comparator 250 may compare a first voltage V1 input from the first test bump 211 with the reference voltage Vref input from the voltage supply unit 240.

To this end, a first input terminal 251 of the comparator 250 may be coupled to the first test bump 211, and a second input terminal 252 of the comparator 250 may be coupled to the voltage supply unit 240.

Thus, the first voltage V1 of the first test bump 211 can be input to the first input terminal 251 of the comparator 250, and the reference voltage Vref of the voltage supply unit 240 can be input to the second input terminal 252 of the comparator 250.

The comparator 250 may output a comparison result between the first voltage V1 and the reference voltage Vref through an output terminal 253 thereof.

For example, the comparator 250 may output a first result signal S1 when the difference between the first voltage V1 and the reference voltage Vref is within a specific error range.

The comparator 250 may output a second result signal S2 when the difference between the first voltage V1 and the reference voltage Vref is not within the specific error range.

For example, the first result signal Si may be set to a high-level voltage, and the second result signal S2 may be set to a low-level voltage.

In this case, the result signal S1 or S2 may be stored in a second register unit 232.

The test power unit 270 may supply a test voltage Vtest (e.g., a predetermined test voltage Vtest) to the second test bump 212.

The reference resistor Rref may be coupled to the first test bump 211. Thus, the reference resistor Rref can also be coupled to the first input terminal 251 of the comparator 250.

Through the configuration described above, the relationship between the first voltage V1 and the test voltage Vtest may be represented by the following equation.

V1={Rref/(Rb+Rref)}*Vtest, Equation 1

wherein V1 is the first voltage, Rref is the reference resistance, Rb is the bonding resistance, and Vtest is the test voltage.

Here, the bonding resistance Rb refers to a sum of the first bonding resistance R1 and the second bonding resistance R2.

Hereinafter, an operation to calculate the bonding resistance Rb of the system according to the present embodiment will be described.

The test power unit 270 supplies the test voltage Vtest to the second test bump 212.

Accordingly, the first voltage V1 input to the comparator 250 may have the level of a voltage represented by Equation 1 described above.

The voltage supply unit 240 supplies the reference voltage Vref to the comparator 250. The voltage supply unit 240 may change the reference voltage Vref when the second result signal S2 is output from the comparator 250.

When the second result signal S2 is output from the comparator 250, the controller 300 may change the reference value stored in the first register unit 231 by controlling the first register unit 231, thereby causing the voltage supply unit 240 to change the reference voltage Vref.

For example, the controller 300 reads the second result signal S2 stored in the second register unit 232. The controller 300 may cause the reference value of the first register unit 231 to be changed according to the read second result signal S2.

Alternatively, the first register unit 231 may automatically change the reference value by reflecting (e.g., in response to) the second result signal S2 output from the comparator 250 without any control performed by the controller 300.

For example, the first register unit 231 reads the second result signal S2 stored in the second register unit 232, and the reference value may be changed according to the second result signal S2.

Through the process in which the voltage supply unit 240 changes the reference voltage Vref, the reference voltage Vref may be equal to or approximately equal to to the first voltage V1.

Accordingly, the comparator 250 can output the first result signal S1 when the difference between the first voltage V1 and the reference voltage Vref is within a specific error range.

When the first result signal S1 is output from the comparator 250, the controller 300 may calculate a bonding resistance Rb, using the reference voltage Vref, the reference resistance Rref and the test voltage Vtest.

For example, the comparator 250 may detect the reference voltage Vref input to the comparator 250 by reading a reference value currently stored in the first register unit 231.

When the reference voltage Vref is equal to the first voltage V1 or within the specific error range, the first voltage V1 may be replaced with the reference voltage Vref in Equation 1.

Therefore, Equation 1 may be replaced by Equation 2.

Vref={Rref/(Rb+Rref)}*Vtest, Equation 2

wherein Vref is the reference voltage, Rref is the reference resistance, Rb is the bonding resistance, and Vtest is the test voltage.

The reference voltage Vref, the reference resistance Rref and the test voltage Vtest are previously known values in an example embodiment, and thus the controller 300 can calculate the bonding resistance Rb through Equation 2.

By way of summation and review, according to embodiments of the present invention, it is possible to provide a system for inspecting a display panel, which can automatically measure a bonding resistance generated by the bonding between the display panel and a driving circuit unit.

Further, it is possible to provide a system for inspecting a display panel, in which components for measuring the bonding resistance are built in the driving circuit unit, thereby increasing convenience in the measurement of a bonding resistance.

Example embodiments have been disclosed herein, and although specific terms are employed, they are used and are to be interpreted in a generic and descriptive sense only and not for the purposes of limitation. In some instances, as would be apparent to one of ordinary skill in the art at the time of filing the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims, and their equivalents.

What is claimed is:

1. A system for inspecting a display panel having a non-display area and a display area comprising a plurality of pixels, the system comprising:
first and second test pads in the non-display area;
a driving circuit in the non-display area, the driving circuit comprising first and second test bumps respectively bonded to the first and second test pads; and
a controller to calculate a bonding resistance between the first and second test pads and the first and second test bumps.

2. The system of claim 1, wherein the display panel further comprises a coupling line configured to couple the first and second test pads to each other.

3. The system of claim 2, wherein the driving circuit further comprises:
a first register to store a reference value;
a voltage supply unit to output a reference voltage corresponding to the reference value;
a comparator to compare a first voltage input from the first test bump with the reference voltage; and
a test power unit to supply a test voltage to the second test bump.

4. The system of claim 3, wherein the driving circuit further comprises a reference resistor coupled to the first test bump.

5. The system of claim 4, wherein the comparator is configured to output a first result signal when a difference between the first voltage and the reference voltage is within a specific error range, and to output a second result signal when the difference between the first voltage and the reference voltage is not within the specific error range.

6. The system of claim 5, wherein the first register is configured to change the reference value when the second result signal is output from the comparator.

7. The system of claim 5, wherein the controller is configured to change the reference value stored in the first register when the second result signal is output from the comparator.

8. The system of claim 5, wherein the controller is configured to calculate the bonding resistance, using the reference voltage, the reference resistance and the test voltage, when the first result signal is output from the comparator.

9. The system of claim 8, wherein the controller is configured to calculate the bonding resistance, using the following equation:
Vref={Rref/(Rb+Rref)}*Vtest,
wherein Vref is the reference voltage, Rref is the reference resistance, Rb is the bonding resistance, and Vtest is the test voltage.

10. The system of claim 5, wherein the voltage supply unit is configured to change the reference voltage when the second result signal is output from the comparator.

11. The system of claim 1, wherein the system further comprises a plurality of data pads in the non-display area, and a plurality of data lines coupled between the data pads and the pixels.

12. The system of claim 11, wherein the system further comprises a plurality of scan pads in the non-display area, and a plurality of scan lines coupled between the scan pads and the pixels.

13. The system of claim 12, wherein the driving circuit further comprises a plurality of data bumps coupled to the data pads, and a data driver to supply data signals to the data bumps.

14. The system of claim 13, wherein the driving circuit further comprises a plurality of scan bumps coupled to the scan pads, and a scan driver to supply scan signals to the scan bumps.
